(19) United States
(12) Patent Application Publication
(10) Pub. No.: US 2013/0215590 A1
(43) Pub. Date: Aug. 22, 2013

(54) CABLE POSITIONING MECHANISM AND ELECTRONIC DEVICE USING THE SAME

(71) Applicants: NA WANG, Shenzhen City (CN); XUE-FENG WAN, Shenzhen City (CN)

(72) Inventors: NA WANG, Shenzhen City (CN); XUE-FENG WAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/466,151

(22) Filed: May 8, 2012

(30) Foreign Application Priority Data
Feb. 21, 2012 (CN) 201210038768.9

(51) Int. Cl. H05K 7/02; F16L 3/10

(52) U.S. Cl. 361/807; 248/65

(57) ABSTRACT

A cable positioning mechanism to hold a cable in position includes a first positioning member and a second positioning member. The first positioning member includes a first main body having a first edge, and a first support member and a first blocking member protruding from the first edge. The first support member is spaced apart from the first blocking member to form a first opening. The second positioning includes a second main body having a second edge, and a second support member and a second blocking member protruding from the second edge. The second support member is spaced apart from the second blocking member to form a second opening. The first and the second openings communicate with each other to cooperatively form a space for receiving the cable.

### BACKGROUND

1. Technical Field

The present disclosure relates to positioning mechanisms, and particularly, to a cable positioning mechanism and an electronic device using the cable positioning mechanism.

2. Description of Related Art

An electronic device typically includes a variety of cables for electrically connecting different electronic components. However, most of the time, the cables in the electronic device may become disorderly, for example, the cables respectively arranged on the upper cover and the bottom cover of the electronic device may be tangled when the upper cover and the bottom cover are disassembled from each other by accident.

Therefore, what is needed is a means to solve the problems described above.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an isometric view of an electronic device in accordance with an exemplary embodiment.

FIG. 2 is a partially disassembled isometric view of the electronic device of FIG. 1 in which an upper cover is omitted.

FIG. 3 is an isometric view of a cable positioning mechanism used in the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

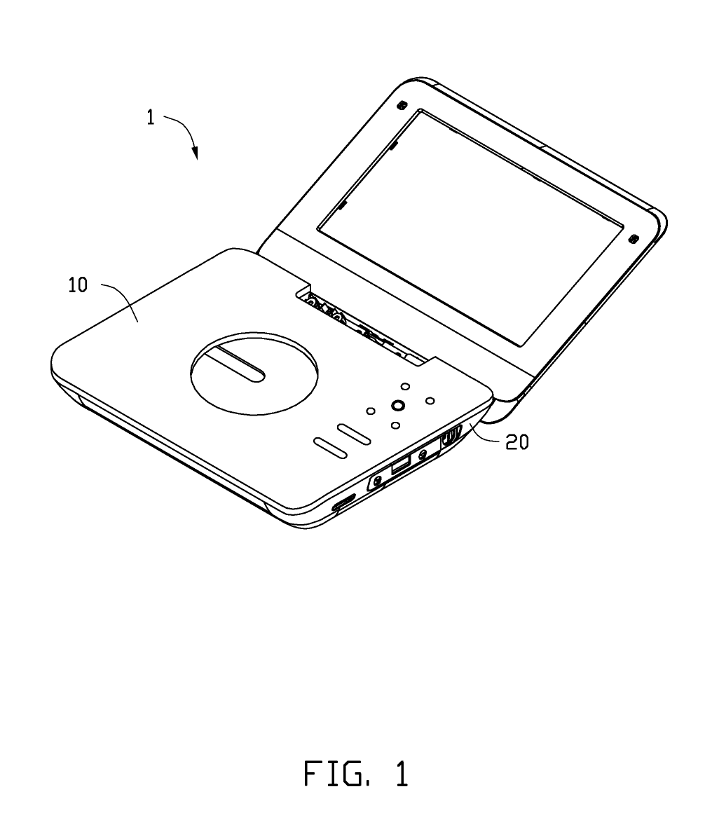

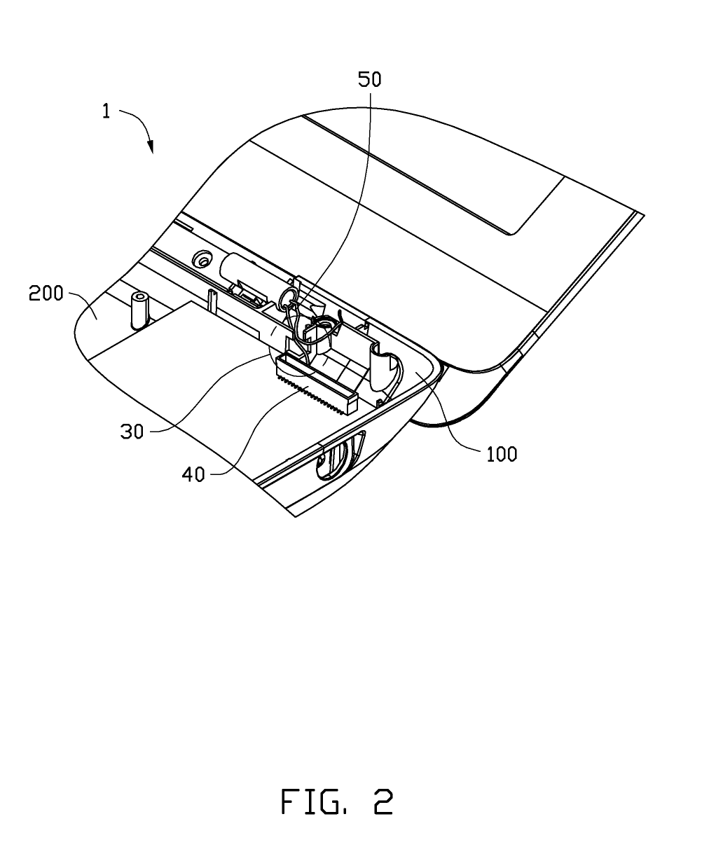

FIGS. 1-2, is an exemplary embodiment of an electronic device 1. The electronic device 1 includes an upper cover 10 and a bottom cover 20 connected to the upper cover 10. The upper and the bottom covers 10, 20 cooperatively form a receiving space 100 for receiving at least one electronic component 40, at least one cable 50 including one end connected to the electronic component 40, and a cable positioning mechanism 30 for holding the cable 50.

The upper cover 10 includes an upper surface 100, and the bottom cover 20 includes a bottom surface 200. In the embodiment, the electronic device 1 includes two electronic components 40. One electronic component 40 is arranged on the bottom surface 200, and the other electronic component 40 (not shown) is arranged on the upper surface 100. Each electronic component 40 is connected with a variety of cables 50. For simplicity, only one cable 50 is shown in FIGS. 1-3.

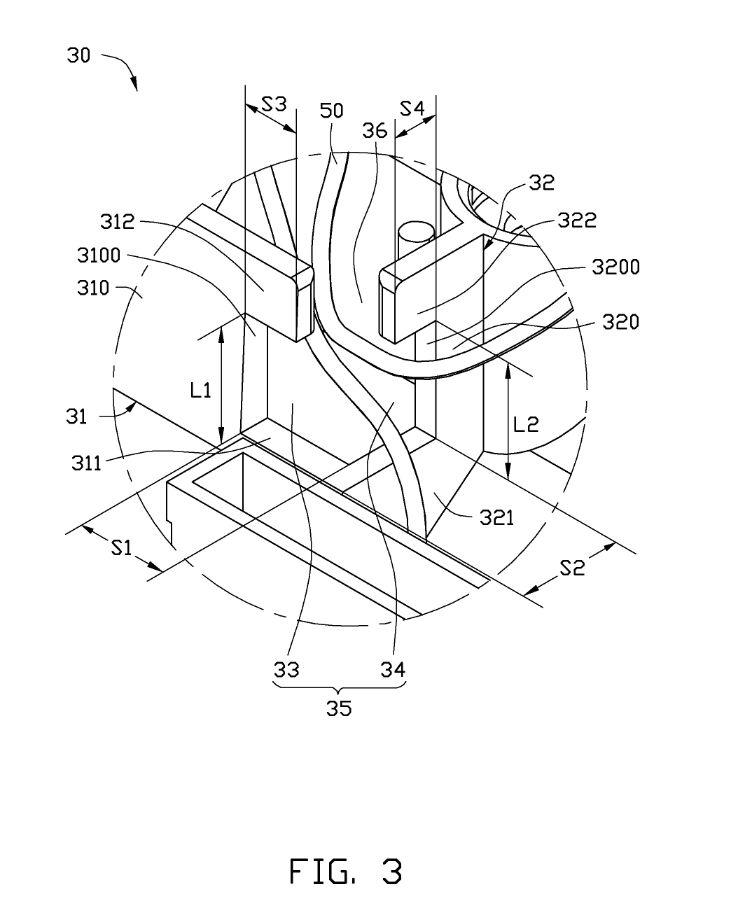

FIG. 3, shows the cable positioning mechanism 30 including a first positioning member 31 and a second positioning member 32 which are attached to the bottom surface 200. The first and the second positioning members 31, 32 are connected to each other at their end portions and angled with respect to each other. In the embodiment, the angle between the first and the second positioning member 31, 32 is approximately 90 degrees.

The first positioning member 31 includes a first main body 310 having a first edge 3100, and the second positioning member 32 includes a second main body 320 having a second edge 3200. In the embodiment, a first support member 311 and a first blocking member 312 substantially coplanar with the first main body 310 protrude from the first edge 3100 of the first main body 310. A second support member 321 and a second blocking member 322 substantially coplanar with the second main body 320 protrude from the second edge 3200 of the second main body 320. The first and the second support members 311, 312 are connected to each other respectively at their distal ends. In an alternative embodiment, the first support member 311 and the first blocking member 312 may not be coplanar with the first main body 310, that is, the first support member 311 and the first blocking member 312 may be angled from the first main body 310. Similarly, the second support member 321 and the second blocking member 322 may be angled from the second main body 320.

The first blocking member 312 is formed above the first support member 311 and spaced apart from the first support member 311 by a distance L1, thereby forming a first opening 33 between the first blocking member 312 and the first support member 311. The second blocking member 322 is formed above the second support member 321 and spaced apart from the second support member 321 by a distance L2, thereby forming a second opening 34 between the second blocking member 322 and the second support member 321. The first and the second openings 33, 34 communicate with each other to form a space 35 for receiving the cables 50 therein. Furthermore, the length of the first blocking member 312 (labeled as S3) is less than the length of the first support member 311 (labeled S1). In addition, the length of the second blocking member 322 (labeled S4) is less than the length of the second support member 321(labeled S2), and the first and the second blocking members 312, 322 are substantially aligned with each other, such that the first and the second blocking members 312, 322 form a gap 36 therebetween through which the cables 50 are guided into the space 35.

The size of the space 35 may be varied according to the number of the cables 50 that need to be received in the space 35. For example, each distance L1, distance L2, length S1, and length S2 can be increased when the space 35 receives more cables 50.

During assembly, the first step is to guide the cables 50 into the space 35 through the gap 36, such that the cables 50 can be restricted by the first and the second blocking members 312, 322, and the first and the second sidewalls 3100, 3200. That is, the first and the second blocking members 312, 322 are capable of limiting the movement of the cables 50 along a direction perpendicular to the bottom surface 200, and the first and the second edges 3100, 3200 are capable of limiting the movement of the cables 50 along a direction parallel with the bottom surface 200. When the upper cover 10 is disassembled from the bottom cover 20 by accident, the electronic component 40 arranged at the upper cover 10 moves away from the bottom cover 20, and the cable 50 connected to the electronic component 40 may be forced to move at the same time. However, the disposition of the cavity 35 allows the cable 50 to be held in the cavity 35.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A cable positioning mechanism for being attached to a bottom surface of an electronic device and configured to hold at least one cable in position, comprising:
a first positioning member attached to the bottom surface, comprising:
a first main body comprising a first edge; and
a first support member and a first blocking member protruding from the first edge, the first blocking member being arranged above and spaced apart from the first support member, forming a first opening; and
a second positioning member attached to the bottom surface, comprising:
a second main body comprising a second edge; and
a second support member and a second blocking member protruding from the second edge, the second blocking member being arranged above and spaced apart from the second support member, forming a second opening, the second opening communicating with the first opening to cooperatively form a space to hold the cable therein.

2. The cable positioning mechanism of claim 1, wherein a length of the first blocking member is less than a length of the first support member, and a length of the second blocking member is less than a length of the second support member, and the first and the second blocking members are substantially aligned with each other, allowing the first and the second blocking members to form a gap therebetween through which the cable is guided into the space.

3. The cable positioning mechanism of claim 1, wherein the first support member and the second support members are connected to each other at distal ends thereof opposite to the first and the second main bodies.

4. The cable positioning mechanism of claim 2, wherein an angle between the first and the second support members is 90 degrees.

5. The cable positioning mechanism of claim 1, wherein the first support member and the first blocking member are coplanar with the first main body, and the second support member and the second blocking member are coplanar with the second main body.

6. An electronic device, comprising:
an upper cover;
a bottom cover connected to the upper cover to form a receiving space;
a cable positioning mechanism received in the space and configured to hold at least one cable in position, comprising:
a first positioning member attached to the bottom surface, comprising:
a first main body comprising a first edge; and
a first support member and a first blocking member protruding from the first edge, the first blocking member being arranged above and spaced apart from the first support member, forming a first opening; and
a second positioning member attached to the bottom surface, comprising:
a second main body comprising a second edge; and
a second support member and a second blocking member protruding from the second edge, the second blocking member being arranged above and spaced apart from the second support member, forming a second opening, the second opening communicating with the first opening to cooperatively form a space to hold the cable therein.

7. The electronic device of claim 6, wherein a length of the first blocking member is less than a length of the first support member, and a length of the second blocking member is less than a length of the second support member, and the first and the second blocking members are substantially aligned with each other, allowing the first and the second blocking members to form a gap therebetween through which the cable is guided into the space.

8. The electronic device of claim 6, wherein the first support member and the second support members are connected to each other at distal ends thereof opposite to the first and the second main bodies.

9. The electronic device of claim 7, wherein an angle between the first and the second support members is 90 degrees.

10. The electronic device of claim 6, wherein the first support member and the first blocking member are coplanar with the first main body, and the second support member and the second blocking member are coplanar with the second main body.
